(19) United States
(12) Patent Application Publication
(10) Pub. No.: US 2025/0172607 A1
(43) Pub. Date: May 29, 2025

(54) AUTOMATIC MAVERICK WAFER SCREENING USING MEASURED DIE PARAMETER AGAINST HISTORIC DIE PARAMETER

(71) Applicant: Infineon Technologies Canada Inc., OTTAWA (CA)

(72) Inventors: Iman ABDALI MASHHADI, Kanata (CA); Regina Inyangat AKUDO, Kanata (CA); Syed Faizan-ul-Haq GILANI, Stittsville (CA)

(21) Appl. No.: 18/521,716

(22) Filed: Nov. 28, 2023

(51) Int. Cl. G01R 31/28

(52) U.S. Cl. CPC G01R 31/2831

(57) ABSTRACT

Automatic maverick screening of a semiconductor wafer taking into account historical position-dependence of a measured parameter. For each of multiple die on a subject wafer being screened, a die screening is performed that includes measuring the parameter value at the position and comparing against a historically expected parameter value at that position. This comparison results in a deviation between the measured and expected parameter values of the die at that position. Then, a deviation parameter value of the subject wafer is calculated using the deviation value of the plurality of die on the subject wafer. The subject wafer is identified as a maverick wafer if the deviation parameter value of the subject wafer falls outside of a deviation tolerance.

### BACKGROUND

Integrated circuits are often manufactured by performing a series of processing steps on a semiconductor wafer. The wafer is a thin flat disc of semiconductor material, most commonly silicon. The wafer undergoes several processing steps where various electronic circuits are formed on the surface of the wafer. Each integrated circuit is manufactured in a dedicated area of the semiconductor wafer in a grid pattern. Once the wafer is fully processed with an integrated circuit formed in each dedicated area of the grid pattern, the semiconductor wafer is diced along the grid pattern into constituent die. Such a die is often termed as a “chip”. Each die on the wafer typically has the same electronic circuit, and the wafer can contain from just a few dies to thousands of dies, depending on the size of the wafer and the size of each die.

After dicing, each die is often tested to ensure functionality. Dies that fail the test are marked and discarded. Testing may occur prior to dicing (called “wafer-level testing”) and some testing may occur after dicing (called “chip-level testing”). In any case, functional dies are then packaged to protect them and to provide connections (usually through pins or solder balls) to external devices or circuits. Testing performed on the package as a whole is referred to as “package-level testing”. Functional packages can be mounted on circuit boards and used in a wide array of electronic devices.

There are sometimes instances in which something unexpected occurred while processing a wafer, which will result in the wafer being considered as an outlier that varies too far from specification. Such a wafer is often termed a “maverick wafer”. For instance, perhaps an unexpected environment was encountered, or perhaps a processing machine malfunctioned. Accordingly, maverick screening is often performed to identify maverick wafers and to thereafter determine what adjustments or corrections can be made in the manufacturing process or environment to correct the manufacturing issues. Furthermore, the maverick wafer my be processed uniquely by for example, discarding the wafer entirely, or perhaps more conservatively selecting die to discard. For instance, if the maverick wafer is considered as such because the wafer has a region that shows anomalous measurements, perhaps die both within the region and within the proximity of the region may be marked for discarding.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Embodiments described herein relate to automatic maverick screening of a semiconductor wafer. In the normal processing of a wafer, a given parameter may be expected to vary in a particular way depending on the position on the wafer. For instance, for one parameter, it may be completely normal to have lower measurements towards the center of a wafer, and higher measurements towards the edge of the wafer. Thus, for a given parameter, the position-specific dependence (often termed the “expected heat map”) of that parameter may be expected to have a certain pattern on the wafer. However, for another parameter (a “second parameter”), the normal position-specific dependence of the second parameter may be quite different than the normal position-specific dependence of the first parameter.

Experienced semiconductor testing engineers may be able to judge whether the heat map pattern for a particular parameter varies from an expected heat map such as to suggest that the wafer is a maverick wafer. However, in accordance with the principles described herein, maverick wafer detection is automatically determined for a given parameter notwithstanding the parameter-specific nature of what an expected heat map would look like.

Specifically, for each of multiple die on a subject wafer being screened, a die screening is performed. The die screening includes measuring a parameter of the die. That measured parameter value is compared against an expected parameter value. That expected parameter value is dependent on a history of measured parameter values of the parameter of previous dies at a same position for previously screened wafers. This comparison results in a deviation between the measured parameter value of the die at that position and the expected parameter value of the die for that position. This die screening is performed for multiple die of the wafer for comparing against historically expected parameter values for die at the respective position. Note that this history is specific to the position of the die on the wafer, and thus would take into account specific variances based on wafer position that are specific to that particular parameter.

Then, a deviation parameter value of the subject wafer is calculated using the deviation value of the plurality of die on the subject wafer. The subject wafer is identified as a maverick wafer if the deviation parameter value of the subject wafer falls outside of a deviation tolerance. This maverick screening is automatically performed. Accordingly, more maverick screening may be performed without requiring manual intervention. Furthermore, maverick wafers may be detected earlier since manual intervention is not required. This identified maverick wafer may then be further evaluated to make earlier corrections to the manufacturing process.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 illustrates nine examples of position-specific dependencies on a wafer;

FIG. 2 illustrates a plan view of a semiconductor wafer that includes sixteen dies configured in a four-by-four grid, which is used for a simple example of a subject wafer that is being automatically screened for maverick detection;

FIG. 3 illustrates a flowchart of a method for automatically performing maverick screening of a semiconductor wafer, in accordance with the principles described herein;

FIG. 4 illustrates a flowchart of a method for adjusting the position-specific expected parameter values in accordance with the principles described herein;

FIG. 5 illustrates a flowchart of a method for automatically performing maverick screening of a semiconductor wafer, and represents a specific example of the method of FIG. 3;

FIG. 6A illustrates a position-wise visual representation of example measured parameter values of a subject wafer, in which a central ring area and an offset area are each showing higher measurements;

FIG. 6B illustrates a visual representation of FIG. 6A, but with the values inverted such that the central ring area and the offset area each have lower values;

FIG. 6C illustrates a visual representation of position-wise expected historical values for the parameter, showing the higher measurements in the central ring area are historically expected, but that higher measurements in the offset area are not historically expected;

FIG. 6D illustrates a visual representation a position-wise result of multiplying the data from FIG. 6B with the data from FIG. 6C; and

FIG. 7 illustrates a functional block-diagram of a computing system that may be used to perform the methods of FIG. 3, 4, or 5.

### DETAILED DESCRIPTION

Embodiments described herein relate to automatic maverick screening of a semiconductor wafer. In the normal processing of a wafer, a given parameter may be expected to vary in a particular way depending on the position on the wafer. For instance, for one parameter, it may be completely normal to have lower measurements towards the center of a wafer, and higher measurements towards the edge of the wafer. Thus, for a given parameter, the position-specific dependence (often termed the “expected heat map”) of that parameter may be expected to have a certain pattern on the wafer. However, for another parameter (a “second parameter”), the normal position-specific dependence of the second parameter may be quite different than the normal position-specific dependence of the first parameter.

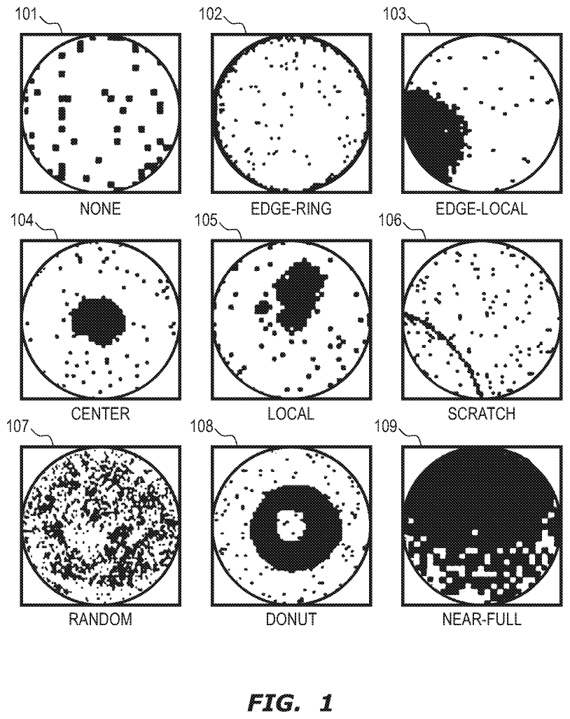

FIG. 1 illustrates nine examples 101 through 109 of position-specific dependencies of a measured parameter on a wafer. Here, dies having measured parameter values that fall outside of a specific tolerance are represented by dark areas, and dies that have the measured parameter values that falls inside of a specific tolerance are represented by light areas. Herein, the term “die” is used to refer to a region on the semiconductor wafer that includes circuitry. Later, each die will be separated by a dicing process into individual die. Notice that each of the nine examples 101 through 109 show a particular example pattern of die that fall outside of the tolerance. Some of these patterns may be quite normal for a given parameter and some may be quite abnormal for a given parameter. Furthermore, a pattern that may be considered normal for one parameter may not at all be normal for another parameter. For instance, a donut pattern of example 108 may be normal for one parameter, but not for another. Some patterns may be abnormal for any parameter. For instance, pattern 106 is indicative of a mechanical scratch occurring on the wafer.

Thus, maverick wafer detection typically involves an experienced semiconductor testing engineer manually evaluating (using their experience) whether the measured heat map pattern for a particular parameter varies from what the engineer might expect such as to suggest that the wafer is a maverick wafer. However, in accordance with the principles described herein, maverick wafer detection is automatically determined for a given parameter notwithstanding the parameter-specific nature of what an expected heat map would look like.

Specifically, for each of multiple die on a subject wafer being screened, a die screening is performed. The die screening includes measuring a parameter of the die. The measured parameter value from the die screening is compared against an expected parameter value. That expected parameter value is dependent on a history of measured parameter values of the parameter of previous dies at a same position for previously screened wafers. This comparison results in a deviation between the measured parameter value of the die at that position and the expected parameter value of the die for that position. This die screening is performed for multiple die of the wafer for comparing against historically expected parameter values for die at the respective position. Note that this history is specific to the position of the die on the wafer, and specific to the particular parameter, and thus would take into account specific variances based on wafer position for that particular parameter.

After the die screenings are performed, a deviation parameter value of the subject wafer is calculated using the deviation value of the multiple die on the subject wafer. The subject wafer is identified as a maverick wafer if the deviation parameter value of the subject wafer falls outside of a deviation tolerance. This maverick screening is automatically performed. Accordingly, more maverick screening may be performed without requiring manual intervention. Furthermore, maverick wafers may be detected earlier since manual intervention is not required. This identified maverick wafer may then be further evaluated to make earlier corrections to the manufacturing process.

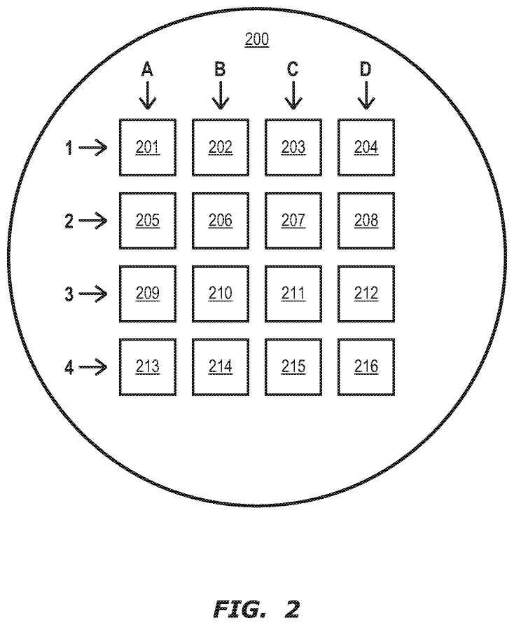

FIG. 2 illustrates a plan view of a semiconductor wafer 200. For simplicity, only sixteen dies 201 through 216 are shown on the semiconductor wafer 200. However, there may be often many more (even hundreds or thousands) of dies on the semiconductor wafer 200, as is the case for the examples of FIG. 1. The example semiconductor wafer 200 of FIG. 2 will be referred to frequently as an example in the description of subsequent figures. The sixteen dies 201 through 216 are positioned in a grid pattern—a four-by-four grid pattern in this example. In the nomenclature used herein, a position of each die is specified by an identification A, B, C or D of its horizontal position followed by an identification 1, 2, 3 or 4 of its vertical position in the grid pattern. As several examples to further clarify the nomenclature, die 202 is at position B1, die 205 is at position A2, die 211 is at position C3, and die 216 is at position D4.

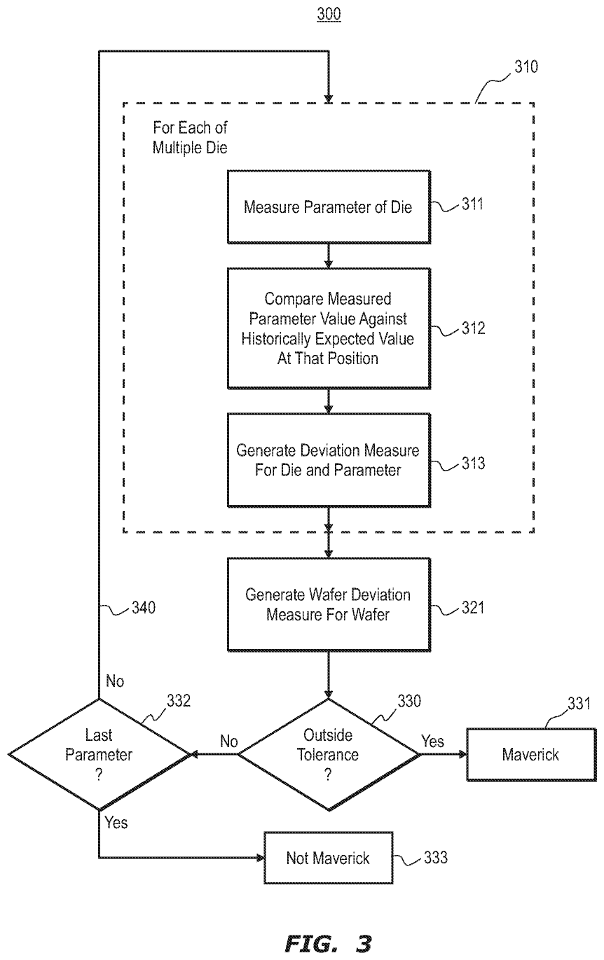

FIG. 3 illustrates a flowchart of a method 300 for automatically performing maverick screening of a semiconductor wafer, in accordance with the principles described herein. As an example, the automated maverick screening may be performed on the semiconductor wafer 200 of FIG. 2. Whatever semiconductor wafer is being screened will also be referred to herein as the “subject wafer”. For instance, if the method 300 is performed to automatically perform maverick screening of the semiconductor wafer 200 of FIG. 2, the semiconductor wafer 200 is the “subject wafer”.

The screening of the subject wafer includes (for each of multiple die on the subject wafer), performing die screening. A die screening is represented by box 310 in FIG. 1. The die screening may be performed for all or perhaps only some of the die on the subject wafer. For instance, if the subject wafer is the semiconductor wafer 200 of FIG. 2, the die screening may be performed for each of the dies 201 through 216. Alternatively, the die screening may be performed for each of only some of the dies 201 through 216. Thus, in some embodiments, only a sampling of the die on a subject wafer are subject to the die screening. Such sampling might particularly be useful where there are a large number of die on the subject wafer, and general pattern of the measured values can be obtained by sampling.

The die screening 310 includes measuring a parameter of the die at a position to obtain a measured parameter value of a parameter (act 311). The parameter is of the circuit on the die. As an example, suppose that the circuit includes a power transistor. In that case, the parameter might be an on-resistance of the power transistor, or perhaps a leakage current of the power transistor. The die screening 310 may be performed for each of multiple parameters of the die. However, for now, a single performance of the die screening 310 will be described with respect to a particular die (also called herein a “first die”) and to a particular parameter (also called herein a “first parameter”). Referring to FIG. 2, if the subject wafer was the semiconductor wafer 200, the “first die” being subject to die screening might be the die 201, but could be any of the other die. However, for this example, suppose that the first die being subjected to die screening 310 is the die 201 at position A1 in FIG. 2.

As part of the die screening 310 of the first parameter of the first die, the measured parameter value of that first parameter is compared with a historically expected parameter value of the first parameter at the same position (act 312). For instance, if the subject wafer is the semiconductor wafer 200, and the first die is the die 201 at position A1, the measured first parameter is compared with a historically expected parameter value of that first parameter given the position A1. This expectation may indeed be position-dependent. For instance, the expected parameter value at the position A1 may be dependent on a history of the measured parameter values at the same position A1 of previously screened wafers. As a more specific example, the expected parameter value might be a median of the measured parameter value of dies at the same position A1 for a most recent predetermined number of previously screened wafers. In that case, the expected value may be constantly updated as further wafers are automatically screened.

The comparison (of act 312) results in the generation of a deviation (act 313) between the measured parameter value of the die and the expected parameter value of the die. As an example, the deviation may be expressed as a ratio between the measured parameter value and the expected parameter value.

Again, the die screening (act 310) on that first parameter may be performed for multiple die of the subject wafer. For example, the die screening 310 may be performed for die 202 by comparing a measured value of the first parameter of the die 202 against a historically expected value of the first parameter at position A2, and generating a resulting deviation measure for the die 202 and the first parameter. Likewise, the die screening 310 may be performed for die 203 at position A3 to generate a deviation of the measurement for die 203 against the expectation for position A3. Thus, the die screening 310 may be performed for multiple die on the subject wafer.

A deviation parameter value of the subject wafer of the first parameter is then calculated (act 321) for the first parameter using the deviation values of the specific dies on the subject wafer for that first parameter. As an example, the deviation parameter value of the subject wafer for the first parameter might be the median of the deviation values of the die on the subject wafer.

The comparison (of act 312) took into account the position-specific expected value for the first parameter. Accordingly, the overall deviation determined for the entire wafer is dependent on how much the subject wafer deviates from its expected heat map for that first parameter. If the deviation parameter value has a value that falls outside of a deviation tolerance (“Yes” in decision block 330), the subject wafer is identified as a maverick wafer (act 331). This would occur if the subject wafer has a heat map for that first parameter that varies significantly from the expected heat map for that first parameter. Otherwise, (“No” in decision block 330), if that parameter was the last parameter to be evaluated to determined if the subject wafer is a maverick wafer (“Yes” in decision block 332), then the wafer is determined not to be a maverick wafer (act 333).

However, if there are one or more additional parameters to be evaluated to determine if the subject wafer is a maverick wafer (“No” in decision block 332), then the process repeats (as represented by arrow 340) for the next parameter. This is because the described methodology of FIG. 3 works regardless of what the expected heat map is. Accordingly, the method 300 may be repeated for the subject wafer for other parameters as well. As an example, if the dies each included a power transistor, the method 300 may be performed once for the on-resistance of the respective power transistor, again for a first kind of leakage current, and again for another kind of leakage current, and so on. If, during evaluation of any of the parameters, the deviation parameter value of the wafer for a parameter falls outside of a deviation tolerance (“Yes” in decision block 330), the subject wafer may be identified as a maverick wafer.

Then, the process may move onto the next wafer, where the method 300 may again be performed for each of the multiple parameter of the next wafer. Thus, the principles described herein may proceed from one wafer to the next, automatically identifying which of the subject wafers are maverick wafers, and which are not. Since most wafers are not maverick wafers, the use of variance of a measured value against a position-specific expectation for that measured value (where the expectation is based on a median of historical measurements at that position) is an accurate way of detecting maverick wafers.

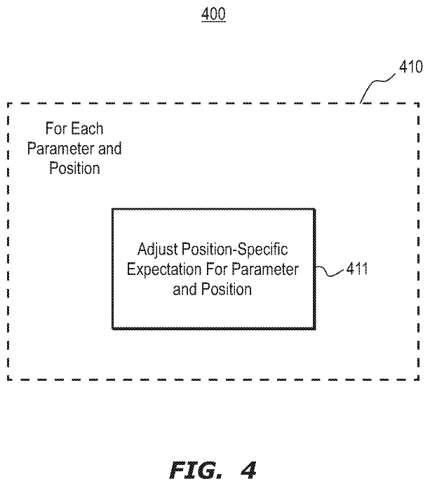

FIG. 4 illustrates a flowchart of a method 400 for adjusting the position-specific expected parameter values in accordance with the principles described herein. As an example, the method 400 may be performed after each wafer screening of a subject wafer. The method 400 includes, for each parameter and position (box 410), adjusting the position-specific dependence of that parameter at that position to include the measured parameter value of that parameter at that position (act 411). For instance, suppose that the position-specific expected values for the parameters depends on the one hundred most recently screened wafers. The values from the oldest of the one hundred previously screened wafers may be dropped, and the measured values from the subject wafer may be added as the most recently screened wafer. Thus, the expected position-specific dependence is updated to account for normal changes in processing conditions.

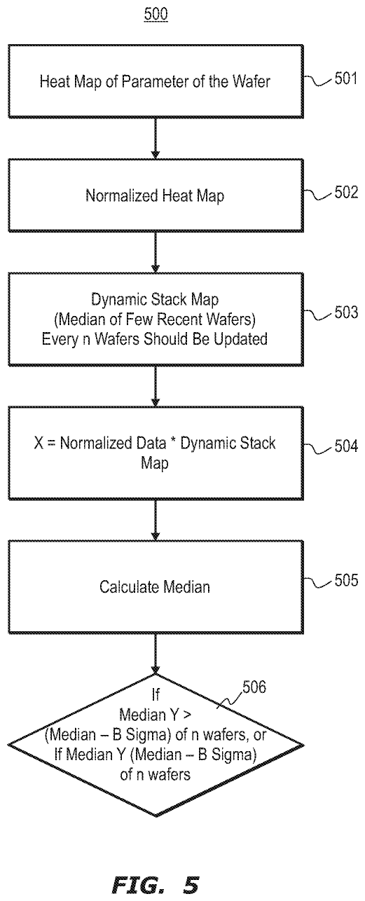

FIG. 5 illustrates a flowchart of a method 500 for automatically performing maverick screening of a semiconductor wafer, and represents a specific example of the method 300 of FIG. 3. The method 500 includes generating a heat map of measured values of a parameter (act 501). This may be accomplished by measuring the value of the parameter for each die on the subject wafer. In other words, the heat map may be generated by performing act 311 of the method 300 for each die on the subject wafer.

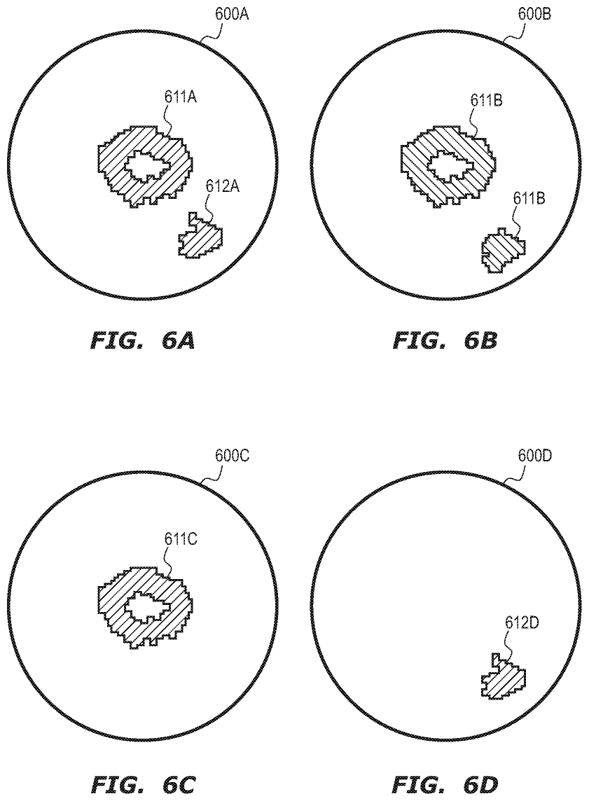

FIGS. 6A through 6D each illustrate a position-wise visual representations of example data of at respective stages of processing of the method of FIG. 5. The presentation of position-wise visual representations (or “heat maps”) in FIGS. 6A through 6D is merely for convenience of the reader in understanding the data being tracked at the respective time of operation of the method of FIG. 5. The heat map need not be visualized to the user, as the detection of maverick wafers is an automated process. It is just that the computing system will track measured values against respective position on the wafer.

FIG. 6A illustrates a position-wise visual representation 600A (or heat map 600A) of example measured parameter values of a subject wafer, where the measured value is represented at its respective position on the subject wafer. In the visual representation, right-leaning cross hatching represents areas where the values are higher than in areas that are not cross-hatched. Notice that there are two areas that show high measurements including a ring area 611A close to the center of the wafer, and an offset area 612A that is offset from center to the lower right. Suppose in this example that the ring area 611A is where the parameter being measured is historically expected to have higher measurements, whereas the offset area 612A is an area where the parameter is not historically expected to have higher measurements. Thus, the higher values in the ring area 611A might not indicate that the subject wafer is a maverick wafer. However, the higher values in the offset area 612A might indicate that the subject wafer is a maverick wafer. In this particular example, the ring area 611A is typical for the parameter being measured. However, because the principles described herein use the historical measurements to determine where the typical measured parameters might be expected to be lower or higher, the principles described herein work regardless of whether there is a ring area that represents historically expected values.

Referring to FIG. 5, after the measurements are taken, each measured value of the parameter is normalized (act 502). As an example, suppose the measured value is X, the normalized value might be the inverse of X (or in other words, 1/X, read “one over X”). The heat map 600B of FIG. 6B may result. There is still a ring area 611B that corresponds generally to the ring area 611A of the heat map 600A, and an offset area 612B that corresponds generally to the offset area 612A of the heat map 600A. However, since the heat map 600B is the position-wise inverse of the heat map 600A, the areas 611B and 612B are lower values as represented by the left-leaning cross-hatching.

Next, a stack map is obtained (act 503). The stack map is the position-dependent expected value of the parameter. Suppose that the expected value at each position is represented by Xref. Referring to FIG. 6C, the heat map 600C is an example of that stack map. The stack map may be the position-dependent expected value of the parameter given the most recent “n” measured wafers (where “n” is some number-perhaps one hundred in an example). For instance, the expected value at a position might be the median measured value of the most recent n number of wafers.

As previously mentioned, for the parameter, there is expected to be higher values in a ring shape near the center of the wafer. Accordingly, the heat map 600C includes a ring shape 611C of higher values. However, the heat map 600C does not include a high value region corresponding to the offset area 612B of heat map 600B, or corresponding to the offset area 612A of heat map 600A. This is because the higher measurements of the parameter in that offset area are historically anomalous.

Next, a heat map of the deviations from the expectation is determined (act 504). This may be performed by (for each position) multiplying the value from the heat map 600B against the value from the heat map 600C to obtain the heat map 600D. That may be represented by the equation Y=Xref*1/X, where Y is the value at each position in the heat map 600D. This operation results in whichever areas that deviate from the expected value being identified. If the wafer was not a maverick, then the heat map 600D would have relatively uniform values (within a particular tolerance) regardless of position. However, the wafer is a maverick wafer due to the offset area 612A having higher than expected measured values. Accordingly, that deviation from expectation is reflected in the offset area 612D appearing in the heat map 600D.

Next, the median value of all values Y from the heat map is calculated (act 505), and used to determine whether the parameter measurements indicate that the wafer is a maverick wafer (decision block 506). If the median of Y deviates by a particular tolerance from the expected median of Y for a previous number of wafers, then the wafer is deemed a maverick wafer. For instance, if the median of Y is more than or less than three sigma (three standard deviations) or perhaps more than or less than six sigma away from the distribution of medians of Y for the prior n screened wafers, then the wafer may be deemed a maverick wafer.

Thus, the principles described herein provide an effective mechanism to automatically and accurately perform maverick wafer detection, allowing for earlier maverick detection and without requiring manual intervention to perform the identification.

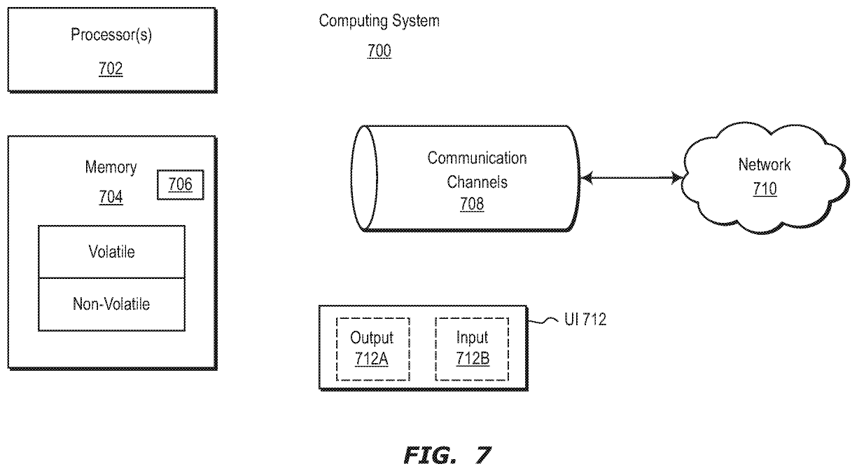

Methods 300, 400 and 500 may be performed by a computing system, such as the computing system 700 described below with respect to FIG. 7. As illustrated in FIG. 7, in its most basic configuration, a computing system 700 includes at least one hardware processing unit 702 and memory 704. The processing unit 702 includes a general-purpose processor. Although not required, the processing unit 702 may also include a field programmable gate array (FPGA), an application specific integrated circuit (ASIC), or any other specialized circuit. In one embodiment, the memory 704 includes a physical system memory. That physical system memory may be volatile, non-volatile, or some combination of the two. In a second embodiment, the memory is non-volatile mass storage such as physical storage media. If the computing system is distributed, the processing, memory and/or storage capability may be distributed as well.

The computing system 700 also has thereon multiple structures often referred to as an “executable component”. For instance, the memory 704 of the computing system 700 is illustrated as including executable component 706. The term “executable component” is the name for a structure that is well understood to one of ordinary skill in the art in the field of computing as being a structure that can be software, hardware, or a combination thereof. For instance, when implemented in software, one of ordinary skill in the art would understand that the structure of an executable component may include software objects, routines, methods (and so forth) that may be executed on the computing system. Such an executable component exists in the heap of a computing system, in computer-readable storage media, or a combination.

One of ordinary skill in the art will recognize that the structure of the executable component exists on a computer-readable medium such that, when interpreted by one or more processors of a computing system (e.g., by a processor thread), the computing system is caused to perform a function. Such structure may be computer readable directly by the processors (as is the case if the executable component were binary). Alternatively, the structure may be structured to be interpretable and/or compiled (whether in a single stage or in multiple stages) so as to generate such binary that is directly interpretable by the processors. Such an understanding of example structures of an executable component is well within the understanding of one of ordinary skill in the art of computing when using the term “executable component”.

The term “executable component” is also well understood by one of ordinary skill as including structures, such as hard coded or hard wired logic gates, that are implemented exclusively or near-exclusively in hardware, such as within a field programmable gate array (FPGA), an application specific integrated circuit (ASIC), or any other specialized circuit. Accordingly, the term “executable component” is a term for a structure that is well understood by those of ordinary skill in the art of computing, whether implemented in software, hardware, or a combination. In this description, the terms “component”, “agent”, “manager”, “service”, “engine”, “module”, “virtual machine” or the like may also be used. As used in this description and in the case, these terms (whether expressed with or without a modifying clause) are also intended to be synonymous with the term “executable component”, and thus also have a structure that is well understood by those of ordinary skill in the art of computing.

In the description that follows, embodiments are described with reference to acts that are performed by one or more computing systems. If such acts are implemented in software, one or more processors (of the associated computing system that performs the act) direct the operation of the computing system in response to having executed computer-executable instructions that constitute an executable component. For example, such computer-executable instructions may be embodied on one or more computer-readable media that form a computer program product. An example of such an operation involves the manipulation of data. If such acts are implemented exclusively or near-exclusively in hardware, such as within a FPGA or an ASIC, the computer-executable instructions may be hard-coded or hard-wired logic gates. The computer-executable instructions (and the manipulated data) may be stored in the memory 704 of the computing system 700. Computing system 700 may also contain communication channels 708 that allow the computing system 700 to communicate with other computing systems over, for example, network 710.

While not all computing systems require a user interface, in some embodiments, the computing system 700 includes a user interface system 712 for use in interfacing with a user. The user interface system 712 may include output mechanisms 712A as well as input mechanisms 712B. The principles described herein are not limited to the precise output mechanisms 712A or input mechanisms 712B as such will depend on the nature of the device. However, output mechanisms 712A might include, for instance, speakers, displays, tactile output, virtual or augmented reality, holograms and so forth. Examples of input mechanisms 712B might include, for instance, microphones, touchscreens, virtual or augmented reality, holograms, cameras, keyboards, mouse or other pointer input, sensors of any type, and so forth.

Embodiments described herein may comprise or utilize a special-purpose or general-purpose computing system including computer hardware, such as, for example, one or more processors and system memory, as discussed in greater detail below. Embodiments described herein also include physical and other computer-readable media for carrying or storing computer-executable instructions and/or data structures. Such computer-readable media can be any available media that can be accessed by a general-purpose or special-purpose computing system. Computer-readable media that store computer-executable instructions are physical storage media. Computer-readable media that carry computer-executable instructions are transmission media. Thus, by way of example, and not limitation, embodiments of the invention can comprise at least two distinctly different kinds of computer-readable media: storage media and transmission media.

Computer-readable storage media includes RAM, ROM, EEPROM, CD-ROM, or other optical disk storage, magnetic disk storage, or other magnetic storage devices, or any other physical and tangible storage medium which can be used to store desired program code means in the form of computer-executable instructions or data structures and which can be accessed by a general-purpose or special-purpose computing system.

A “network” is defined as one or more data links that enable the transport of electronic data between computing systems and/or modules and/or other electronic devices. When information is transferred or provided over a network or another communications connection (either hardwired, wireless, or a combination of hardwired or wireless) to a computing system, the computing system properly views the connection as a transmission medium. Transmission media can include a network and/or data links which can be used to carry desired program code means in the form of computer-executable instructions or data structures and which can be accessed by a general-purpose or special-purpose computing system. Combinations of the above should also be included within the scope of computer-readable media.

Further, upon reaching various computing system components, program code means in the form of computer-executable instructions or data structures can be transferred automatically from transmission media to storage media (or vice versa). For example, computer-executable instructions or data structures received over a network or data link can be buffered in RAM within a network interface module (e.g., a “NIC”), and then be eventually transferred to computing system RAM and/or to less volatile storage media at a computing system. Thus, it should be understood that storage media can be included in computing system components that also (or even primarily) utilize transmission media.

Computer-executable instructions comprise, for example, instructions and data which, when executed at a processor, cause a general-purpose computing system, special-purpose computing system, or special-purpose processing device to perform a certain function or group of functions. Alternatively, or in addition, the computer-executable instructions may configure the computing system to perform a certain function or group of functions. The computer executable instructions may be, for example, binaries or even instructions that undergo some translation (such as compilation) before direct execution by the processors, such as intermediate format instructions such as assembly language, or even source code.

Although the subject matter has been described in language specific to structural features and/or methodological acts, it is to be understood that the subject matter defined in the appended claims is not necessarily limited to the described features or acts described above, or the order of the acts described above. Rather, the described features and acts are disclosed as example forms of implementing the claims.

### Literal Claim Support Section

Clause 1. A method for automatically performing maverick screening of semiconductor wafers, the method comprising: for each a plurality of die on a subject wafer, measuring a parameter of the die to obtain a measured parameter value; and comparing the measured parameter value to an expected parameter value, the expected parameter value being dependent on a history of measured parameter values of the parameter of previous dies at a same position as the die for previously screened wafers, the comparison resulting in a deviation between the measured parameter value of the die at the position and the expected parameter value of the die at the position; calculating a deviation parameter value of the subject wafer using the deviation value of each of the plurality of die on the subject wafer; and identifying the subject wafer as a maverick wafer if the deviation parameter value falls outside of a deviation tolerance.
Clause 2. The method in accordance with Clause 1, wherein for each of at least some of the plurality of die, the deviation comprises a ratio between the measured parameter value and the expected parameter value.
Clause 3. The method in accordance with Clause 1, the expected parameter value being a median of the measured parameter value of dies at the same position for the previously screened wafers.
Clause 4. The method in accordance with Clause 1, the previously screened wafers being a most recent predetermined number of previously screened wafers.
Clause 5. The method in accordance with Clause 1, for each of the plurality of die on the subject wafer, adjusting the expected parameter value of the parameter at the corresponding position for subsequent maverick wafer screening by adding the measured parameter value of the die to the history of measured parameter values for die at the corresponding position.
Clause 6. The method in accordance with Clause 5, the deviation tolerance being a first deviation tolerance, the subject wafer being a first subject wafer, the method further comprising the following for a second subject wafer, the method further comprising: for each a plurality of die on a second subject wafer, measuring the parameter of the die to obtain a measured parameter value; and comparing the measured parameter value to the adjusted expected parameter value; calculating a deviation parameter value of the second subject wafer using the deviation value of the plurality of die of the second subject wafer; and identifying the second subject wafer as a maverick wafer if the deviation parameter value of the second subject wafer falls outside of the second deviation tolerance.
Clause 7. The method in accordance with Clause 6, the first subject wafer being identified as a maverick because the deviation parameter value of the first subject wafer fell outside of the first deviation tolerance, the second subject wafer not being identified as a maverick because the deviation parameter value of the second subject wafer fell inside of the second deviation tolerance.
Clause 8. The method in accordance with Clause 6, the first deviation tolerance and the second deviation tolerance being the same.
Clause 9. The method in accordance with Clause 1, the calculation of the deviation parameter value of the subject wafer being a median of the deviation values of the plurality of die on the subject water.
Clause 10. The method in accordance with Clause 1, the parameter being a first parameter, the method further comprising the following for each of the plurality of die on the subject wafer: measuring a second parameter of the die to obtain a measured second parameter value; and comparing the measured second parameter value to an expected second parameter value, the expected second parameter value being dependent on a history of measured second parameter values of the second parameter of previous dies at a same position for the previously screened wafers, the comparison of the measured second parameter value to the expected second parameter value resulting in a second deviation between the second measured parameter value of the die and the expected second parameter value of the die.
Clause 11. The method in accordance with Clause 1, each of the plurality of die containing a power transistor.
Clause 12. The method in accordance with Clause 11, the parameter being an on-resistance of the power transistor of the die.
Clause 13. The method in accordance with Clause 11, the parameter being a leakage current of the power transistor of the die.
Clause 14. The method in accordance with Clause 1, the plurality of die on the subject wafer comprising less that all of the die on the subject wafer.
Clause 15. A computer program product comprising one or more computer-readable media having thereon computer-executable instructions that, when executed by one or more processors of a computing system, configure the computing system to automatically performing maverick screening of semiconductor wafers by performing operations comprising: for each a plurality of die on a subject wafer, measuring a parameter of the die to obtain a measured parameter value; and comparing the measured parameter value to an expected parameter value, the expected parameter value being dependent on a history of measured parameter values of the parameter of previous dies at a same position as the die for previously screened wafers, the comparison resulting in a deviation between the measured parameter value of the die at the position and the expected parameter value of the die at the position; calculating a deviation parameter value of the subject wafer using the deviation value of each of the plurality of die on the subject wafer; and identifying the subject wafer as a maverick wafer if the deviation parameter value falls outside of a deviation tolerance.
Clause 16. The computer program product in accordance with Clause 15, the previously screened wafers being a most recent predetermined number of previously screened wafers.
Clause 17. The computer program product in accordance with Clause 15, the subject wafer being a first subject wafer, the method further comprising the following for a second subject wafer: for each of the plurality of die on the second subject wafer: adjusting the expected parameter value for the die at the corresponding position by adding the measured parameter value of the corresponding die of the first parameter value to the history of measured parameter values for die at the corresponding position measuring a parameter of the die to obtain a measured parameter value; and comparing the measured parameter value to the adjusted expected parameter value; calculating a deviation parameter value of the second subject wafer using the deviation value of the plurality of die of the second subject wafer; and identifying the second subject wafer as a maverick wafer if the deviation parameter value of the second subject wafer falls outside of a deviation tolerance.
Clause 18. The computer program product in accordance with Clause 15, the parameter being a first parameter, the method further comprising the following for each of the plurality of die on the subject wafer: measuring a second parameter of the die to obtain a measured second parameter value; and comparing the measured second parameter value to an expected second parameter value, the expected second parameter value being dependent on a history of measured second parameter values of the second parameter of previous dies at a same position for the previously screened wafers, the comparison of the measured second parameter value to the expected second parameter value resulting in a second deviation between the second measured parameter value of the die and the expected second parameter value of the die.
Clause 19. A computing system comprising: one or more processors: one or more computer-readable media having thereon computer-executable instructions that, when executed by one or more processors of a computing system, configure the computing system to automatically performing maverick screening of semiconductor wafers by performing operations comprising: for each a plurality of die on a subject wafer, measuring a parameter of the die to obtain a measured parameter value; and comparing the measured parameter value to an expected parameter value, the expected parameter value being dependent on a history of measured parameter values of the parameter of previous dies at a same position as the die for previously screened wafers, the comparison resulting in a deviation between the measured parameter value of the die at the position and the expected parameter value of the die at the position; calculating a deviation parameter value of the subject wafer using the deviation value of each of the plurality of die on the subject wafer; and identifying the subject wafer as a maverick wafer if the deviation parameter value falls outside of a deviation tolerance.

The present disclosure may be embodied in other specific forms without departing from its essential characteristics. The described embodiments are to be considered in all respects only as illustrative and not restrictive. All changes which come within the meaning and range of equivalency of the claims are to be embraced within their scope.

When introducing elements in the appended claims, the articles “a,” “an,” “the,” and “said” are intended to mean there are one or more of the elements. The terms “comprising,” “including,” and “having” are intended to be inclusive and mean that there may be additional elements other than the listed elements.

What is claimed is:

1. A method for automatically performing maverick screening of semiconductor wafers, the method comprising:
for each a plurality of die on a subject wafer,
measuring a parameter of the die to obtain a measured parameter value; and
comparing the measured parameter value to an expected parameter value, the expected parameter value being dependent on a history of measured parameter values of the parameter of previous dies at a same position as the die for previously screened wafers, the comparison resulting in a deviation between the measured parameter value of the die at the position and the expected parameter value of the die at the position;
calculating a deviation parameter value of the subject wafer using the deviation value of each of the plurality of die on the subject wafer; and
identifying the subject wafer as a maverick wafer if the deviation parameter value falls outside of a deviation tolerance.

2. The method in accordance with claim 1, wherein for each of at least some of the plurality of die, the deviation comprises a ratio between the measured parameter value and the expected parameter value.

3. The method in accordance with claim 1, the expected parameter value being a median of the measured parameter value of dies at the same position for the previously screened wafers.

4. The method in accordance with claim 1, the previously screened wafers being a most recent predetermined number of previously screened wafers.

5. The method in accordance with claim 1, for each of the plurality of die on the subject wafer, adjusting the expected parameter value of the parameter at the corresponding position for subsequent maverick wafer screening by adding the measured parameter value of the die to the history of measured parameter values for die at the corresponding position.

6. The method in accordance with claim 5, the deviation tolerance being a first deviation tolerance, the subject wafer being a first subject wafer, the method further comprising the following for a second subject wafer, the method further comprising:
for each a plurality of die on a second subject wafer,
measuring the parameter of the die to obtain a measured parameter value; and
comparing the measured parameter value to the adjusted expected parameter value;
calculating a deviation parameter value of the second subject wafer using the deviation value of the plurality of die of the second subject wafer; and
identifying the second subject wafer as a maverick wafer if the deviation parameter value of the second subject wafer falls outside of the second deviation tolerance.

7. The method in accordance with claim 6, the first subject wafer being identified as a maverick because the deviation parameter value of the first subject wafer fell outside of the first deviation tolerance, the second subject wafer not being identified as a maverick because the deviation parameter value of the second subject wafer fell inside of the second deviation tolerance.

8. The method in accordance with claim 6, the first deviation tolerance and the second deviation tolerance being the same.

9. The method in accordance with claim 1, the calculation of the deviation parameter value of the subject wafer being a median of the deviation values of the plurality of die on the subject water.

10. The method in accordance with claim 1, the parameter being a first parameter, the method further comprising the following for each of the plurality of die on the subject wafer:
measuring a second parameter of the die to obtain a measured second parameter value; and
comparing the measured second parameter value to an expected second parameter value, the expected second parameter value being dependent on a history of measured second parameter values of the second parameter of previous dies at a same position for the previously screened wafers, the comparison of the measured second parameter value to the expected second parameter value resulting in a second deviation between the second measured parameter value of the die and the expected second parameter value of the die.

11. The method in accordance with claim 1, each of the plurality of die containing a power transistor.

12. The method in accordance with claim 11, the parameter being an on-resistance of the power transistor of the die.

13. The method in accordance with claim 11, the parameter being a leakage current of the power transistor of the die.

14. The method in accordance with claim 1, the plurality of die on the subject wafer comprising less that all of the die on the subject wafer.

15. A computer program product comprising one or more computer-readable media having thereon computer-executable instructions that, when executed by one or more processors of a computing system, configure the computing system to automatically performing maverick screening of semiconductor wafers by performing operations comprising:
for each a plurality of die on a subject wafer,
measuring a parameter of the die to obtain a measured parameter value; and
comparing the measured parameter value to an expected parameter value, the expected parameter value being dependent on a history of measured parameter values of the parameter of previous dies at a same position as the die for previously screened wafers, the comparison resulting in a deviation between the measured parameter value of the die at the position and the expected parameter value of the die at the position;
calculating a deviation parameter value of the subject wafer using the deviation value of each of the plurality of die on the subject wafer; and
identifying the subject wafer as a maverick wafer if the deviation parameter value falls outside of a deviation tolerance.

16. The computer program product in accordance with claim 15, the previously screened wafers being a most recent predetermined number of previously screened wafers.

17. The computer program product in accordance with claim 15, the subject wafer being a first subject wafer, the method further comprising the following for a second subject wafer:
for each of the plurality of die on the second subject wafer:
adjusting the expected parameter value for the die at the corresponding position by adding the measured parameter value of the corresponding die of the first parameter value to the history of measured parameter values for die at the corresponding position;
measuring a parameter of the die to obtain a measured parameter value; and
comparing the measured parameter value to the adjusted expected parameter value;
calculating a deviation parameter value of the second subject wafer using the deviation value of the plurality of die of the second subject wafer; and
identifying the second subject wafer as a maverick wafer if the deviation parameter value of the second subject wafer falls outside of a deviation tolerance.

18. The computer program product in accordance with claim 15, the parameter being a first parameter, the method further comprising the following for each of the plurality of die on the subject wafer:
measuring a second parameter of the die to obtain a measured second parameter value; and
comparing the measured second parameter value to an expected second parameter value, the expected second parameter value being dependent on a history of measured second parameter values of the second parameter of previous dies at a same position for the previously screened wafers, the comparison of the measured second parameter value to the expected second parameter value resulting in a second deviation between the second measured parameter value of the die and the expected second parameter value of the die.

19. A computing system comprising:
one or more processors:
one or more computer-readable media having thereon computer-executable instructions that, when executed by one or more processors of a computing system, configure the computing system to automatically performing maverick screening of semiconductor wafers by performing operations comprising:
for each a plurality of die on a subject wafer,
measuring a parameter of the die to obtain a measured parameter value; and
comparing the measured parameter value to an expected parameter value, the expected parameter value being dependent on a history of measured parameter values of the parameter of previous dies at a same position as the die for previously screened wafers, the comparison resulting in a deviation between the measured parameter value of the die at the position and the expected parameter value of the die at the position;
calculating a deviation parameter value of the subject wafer using the deviation value of each of the plurality of die on the subject wafer; and
identifying the subject wafer as a maverick wafer if the deviation parameter value falls outside of a deviation tolerance.
